(19) United States
(12) Patent Application Publication
(10) Pub. No.: US 2016/0326651 A1
(43) Pub. Date: Nov. 10, 2016

(54) SUBSTRATE PROCESSING APPARATUS

(71) Applicant: TOKYO ELECTRON LIMITED, Tokyo (JP)

(72) Inventor: Masanobu SATO, Kurokawa-gun (JP)

(21) Appl. No.: 15/145,298

(22) Filed: May 3, 2016

(30) Foreign Application Priority Data
May 7, 2015 (JP) 2015-095130

(51) Int. Cl. C23C 16/513

(52) U.S. Cl. CPC C23C 16/513

(57) ABSTRACT

A substrate processing apparatus in which a plurality of substrates is held in a shape of a shelf on a substrate holder, carried into a vertical reaction container and processed by a plasma-state process gas, includes an evacuation mechanism configured to vacuum-evacuate an inside of the vertical reaction container, a plasma-generating chamber configured to protrude toward an outside of the vertical reaction container and to extend in a vertical direction along a sidewall of the vertical reaction container, a process gas-supplying part configured to supply a process gas to the substrates through the plasma-generating chamber, a plasma-generating conductor installed vertically near the plasma-generating chamber outside the reaction container and connected to a high frequency power supply, a plasma-adjusting conductor installed near the vertical reaction container, when viewed from the plasma-generating conductor outside the vertical reaction container, and an impedance-adjusting part installed between the plasma-adjusting conductor and a ground.

### CROSS-REFERENCE TO RELATED APPLICATION

This application claims the benefit of Japanese Patent Application No. 2015-095130, filed on May 7, 2015, in the Japan Patent Office, the disclosure of which is incorporated herein in its entirety by reference.

### TECHNICAL FIELD

The present disclosure relates to a substrate processing apparatus in which a plurality of substrates forming a shape of a shelf held in a substrate holder is carried into a vertical reaction container and in which the substrates are processed by supplying a plasma-state process gas to the substrates.

### BACKGROUND

There is a method of performing a film forming process on the semiconductor wafers (hereinafter, referred as ‘wafers’) held in a shape of a shelf on a wafer boat within a vertical reaction container by converting a gas supplied from a gas supply part into plasma. For example, a portion of a sidewall of the reaction container protrudes outwardly to form a plasma-generating chamber, and high frequency power is applied to an electrode vertically installed outside the plasma-generating chamber so as to generate plasma.

A state of the generated plasma may affect a deposited film. It has been appreciated that if the intensity of plasma is so large that an outer peripheral portion of each of the wafers loaded on the wafer boat is exposed to the plasma, for example, portions of the film near the outer peripheral portion of the film are shrunk and the portions of the film near the outer peripheral portion of the film may be thinner than a central portion of the film. Accordingly, if the intensity of plasma is non-uniform in an arrangement direction of the wafers, in-plane uniformity of the film thickness is varied in the arrangement direction of the wafers. As such, there is a concern that the film deposition processing cannot be performed with good in-plane uniformity. However, since the intensity of plasma depends on a configuration of the electrode, it is difficult to adjust a tendency of the intensity of plasma to vary in the arrangement direction of the wafers by changing processing conditions such as a flow rate or pressure of the gas.

For example, there has been known a configuration in which a serpentine and vertically-extending electrode for generating inductively-coupled plasma is installed in the plasma generating chamber and connected to a high frequency power supply. Further, a grounded ground electrode is disposed outside the plasma generating chamber to prevent the plasma from being generated near the wafers. However, this ground electrode cannot adjust the intensity of plasma in the arrangement direction of the wafers.

### SUMMARY

Accordingly, some embodiments of the present disclosure provide a technique for improving both in-plane processing uniformity and processing uniformity in a wafer arrangement direction for a plurality of substrates in a shape of a shelf held in a substrate holder within a vertical reaction container, when processing the substrates by supplying a plasma-state process gas to the substrates.

According to one embodiment of the present disclosure, there is provided a substrate processing apparatus in which a plurality of substrates is held in a shape of a shelf on a substrate holder, carried into a vertical reaction container and processed by a plasma-state process gas, including an evacuation mechanism configured to vacuum-evacuate an inside of the vertical reaction container, a plasma-generating chamber configured to protrude toward an outside of the vertical reaction container and to extend in a vertical direction along a sidewall of the vertical reaction container, a process gas-supplying part configured to supply a process gas to the substrates through the plasma-generating chamber, a plasma-generating conductor installed vertically near the plasma-generating chamber outside the reaction container and connected to a high frequency power supply, a plasma-adjusting conductor installed near the vertical reaction container, when viewed from the plasma-generating conductor outside the vertical reaction container, and an impedance-adjusting part installed between the plasma-adjusting conductor and a ground.

According to another embodiment of the present disclosure, there is provided a substrate processing apparatus in which a plurality of substrates is held in a shape of a shelf on a substrate holder, carried into a vertical reaction container and processed by a plasma-state process gas, including an evacuation mechanism configured to vacuum-evacuate an inside of the vertical reaction container, a plasma-generating chamber configured to protrude toward an outside of the vertical reaction container and to extend in a vertical direction along a sidewall of the vertical reaction container, a process gas-supplying part configured to supply a process gas to the substrates through the plasma-generating chamber, a plasma-generating conductor installed vertically near the plasma-generating chamber outside the vertical reaction container and connected to a high frequency power supply, and a plasma-adjusting conductor installed near the vertical reaction container when viewed from the plasma-generating conductor outside the vertical reaction container and configured to be divided into a plurality of conductors in a longitudinal direction of the vertical reaction container, wherein impedances between at least two of the divided conductors of the plasma-adjusting conductor and the ground are different from each other.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal sectional view showing a first embodiment of a vertical heat treatment apparatus employing a substrate processing apparatus according to the present disclosure.

FIG. 2 is a cross sectional view showing the vertical heat treatment apparatus.

FIG. 3 is a side view showing the vertical heat treatment apparatus.

FIGS. 4A to 4C are cross sectional views showing the vertical heat treatment apparatus.

FIGS. 5A and 5B are longitudinal sectional views showing the vertical heat treatment apparatus.

FIGS. 6A and 6B are side views and characteristic graphs illustrating operations of the vertical heat treatment apparatus.

FIG. 7 is a schematic perspective view showing a second embodiment of a vertical heat treatment apparatus employing the substrate processing apparatus according to the present disclosure.

FIG. 8 is a cross sectional view showing the vertical heat treatment apparatus.

FIGS. 9A and 9B are longitudinal sectional views showing the vertical heat treatment apparatus.

FIG. 10 is a side view showing a third embodiment of a vertical heat treatment apparatus employing the substrate processing apparatus according to the present disclosure.

FIGS. 11A and 11B are longitudinal sectional views showing the vertical heat treatment apparatus.

FIG. 12 is a characteristic graph showing results of evaluation tests of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

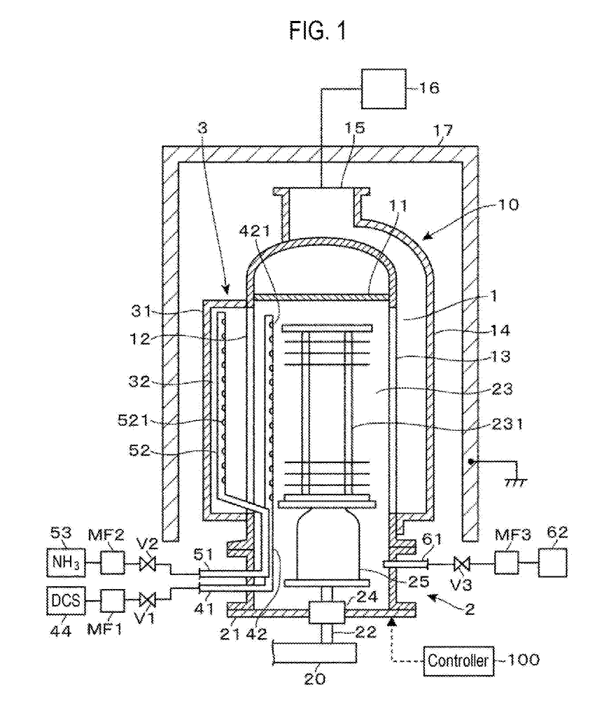

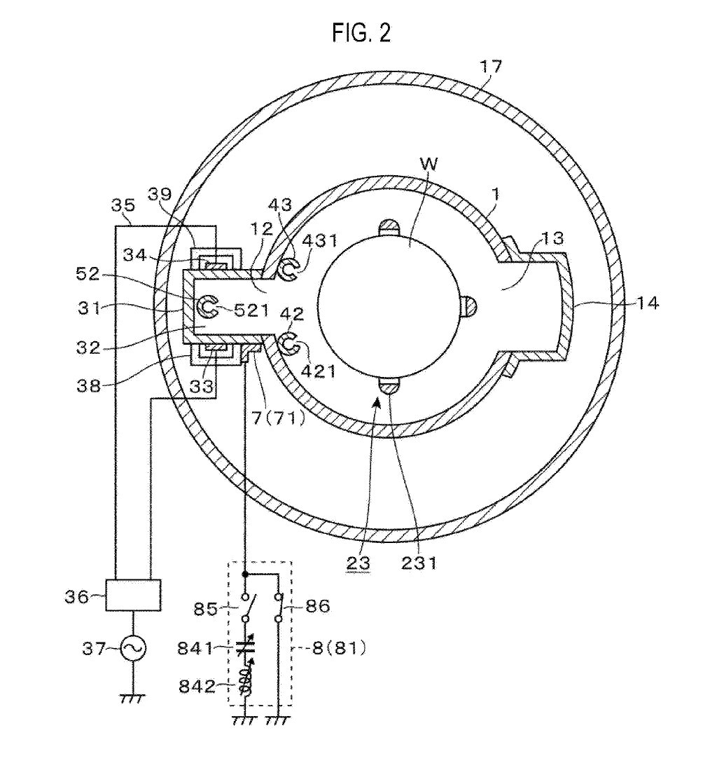

A first embodiment of a vertical heat treatment apparatus employing a substrate processing apparatus according to the present disclosure will be described with reference to FIGS. 1 and 2. FIG. 1 is a longitudinal sectional view of the vertical heat treatment apparatus, and FIG. 2 is a cross sectional view of the vertical heat treatment apparatus. In FIGS. 1 and 2, reference numeral 1 designates a reaction tube formed of a dielectric such as quartz in a vertical cylindrical shape, and a top side of this reaction tube 1 is sealed by a ceiling plate 11 made of quartz. Further, a bottom side of the reaction tube 1 is connected to, for example, a manifold 2 formed of stainless steel in a cylindrical shape, and a reaction container 10 is formed by the reaction tube 1 and the manifold 2. A bottom end of the manifold 2 is opened as a substrate carrying-in/out port, and configured to be hermetically closed by a cover 21 made of quartz and installed on an elevator 20. A rotational shaft 22 is installed through a central portion of the cover 21, and a wafer boat 23 as a substrate holder is mounted on a top end of the rotational shaft 22.

The wafer boat 23 includes a plurality of, e.g., three, posts 231 and supports outer peripheral portions of wafers W to hold the plurality of wafers W in a shape of a shelf. The wafer boat 23 is configured such that it can be carried into the reaction tube 1 and lifted and lowered between a processing position where the substrate carrying-in/out port of the reaction tube 1 is blocked by the cover 21 and a carrying-out position on the bottom side of the reaction tube 1. Moreover, the wafer boat 23 is configured to be rotated about a vertical axis via the rotational shaft 22 by a rotation mechanism 24. Reference numeral 25 in FIG. 1 designates an insulation unit.

An opening 12 is formed in a sidewall of the reaction tube 1, and a plasma-generating part 3 is installed outside the opening 12. The opening 12 is formed to be vertically elongated, e.g., from a position above a top end of the wafer boat 23 to a position below a wafer W positioned at a bottom end of the wafer boat 23, so that active species generated from the plasma-generating part 3 may be supplied to the respective wafers W. This opening 12 is blocked from the outside thereof, for example, by a plasma-generating box 31 made of quartz and having a concave cross-section. As such, a plasma-generating chamber 32 is formed to protrude toward the outside of the reaction tube 1 while extending in a vertical direction along the sidewall of the reaction tube 1. Another configuration of the plasma-generating part 3 will be described later.

In order to vacuum-evacuate the atmosphere in the reaction tube 1, a vertically-elongated evacuation port 13 is formed in a region opposite to the opening 12 in the reaction tube 1. An evacuation cover member 14, for example, made of quartz and having a U-shaped cross-section is installed at the evacuation port 13 to cover the evacuation port 13. The evacuation cover member 14 is configured, for example, to extend vertically along the sidewall of the reaction tube 1 to cover the top side of the reaction tube 1, and a gas outlet 15 is formed, e.g., on a ceiling side of the cover member 14. In order to vacuum-evacuate the inside of the reaction container 10, an evacuation mechanism 16 composed of a vacuum pump and an evacuation flow rate-adjusting part is connected to the gas outlet 15.

A cylindrical shield 17 having a ceiling is installed outside of the reaction tube 1 to surround an outer periphery of the reaction tube 1. This shield 17 is made of a metal and grounded, and has a function of shielding an electric field generated by the plasma-generating part 3. Further, a heater (not shown) is installed on an inner surface of the shield 17 to heat the inside of the reaction tube 1.

A first gas-supplying passage 41 for supplying dichlorosilane (DCS: SiH₂Cl₂) as a silane-based gas, for example, is inserted into a sidewall of the manifold 2, and a leading end of the first gas-supplying passage 41 is bifurcated, for example, to be connected to gas nozzles 42 and 43, respectively. The gas nozzles 42 and 43 are formed of quartz tubes, for example, and installed to extend vertically along the sidewall of the reaction tube 1 at a position that is opposite to the evacuation port 13 and spaced apart from the opening 12. The gas nozzles 42 and 43 are formed with a plurality of gas discharge holes 421 and 431 at a predetermined interval in a longitudinal direction of the gas nozzles, respectively.

An end of a second gas-supplying passage 51 for supplying ammonia (NH₃) gas as a process gas and an end of a replacement gas-supplying passage 61 for supplying nitrogen (N₂) gas as a replacement gas into the reaction tube 1 are inserted into the sidewall of the manifold 2. A gas nozzle 52, which is formed of a quartz tube, for example, and constitutes a process gas-supplying part, is installed at a leading end of the second gas-supplying passage 51. The gas nozzle 52 extends upwards in the reaction tube 1 and is then bent to extend upwards in the plasma-generating chamber 32. The gas nozzle 52 is formed with a plurality of gas discharge holes 521 at a predetermined interval along a longitudinal direction of the gas nozzle 52.

An upstream side of the first gas-supplying passage 41 is connected to a DCS gas-supplying source 44 through a valve V1 and a flow rate controller MF1 in this order. Meanwhile, an upstream side of the second gas-supplying passage 51 is connected to a NH₃ gas-supplying source 53 through a valve V2 and a flow rate controller MF2 in this order. Further, an upstream side of the replacement gas-supplying passage 61 is connected to a N₂ gas-supplying source 62 through a valve V3 and a flow rate controller MF3 in this order. Each of the valves V1 to V3 performs the supply of the gases or the stop of the gases, while the flow rate controllers MF1 to MF3 adjust amounts of supply of the gases.

Next, the plasma-generating part 3 will be described. In describing the plasma-generating part 3, one side of the plasma-generating part 3 close to the wafers W loaded on the wafer boat 23 is referred to as a front side, whereas another side of the plasma-generating part 3 spaced apart from the wafers W is referred to as a rear side. The gas nozzle 52 is disposed at the rear side in the plasma-generating chamber 32 to discharge the NH₃ gas toward the front side. A pair of electrodes 33 and 34, which constitute plasma-generating conductors, are installed respectively to be close to the plasma-generating chamber 32 outside the reaction tube 1. These electrodes 33 and 34 constitute parallel plate electrodes, and are installed to extend vertically from a bottom end of the plasma-generating box 31 to a top end of the plasma-generating box 31 along opposite left and right sidewalls of the plasma-generating box 31, respectively. One end of each of conductive lines 35 is connected to a respective one of the electrodes 33 and 34, whereas the other end of each of the conductive lines 35 is withdrawn outside the shield 17 and connected through a matching circuit 36 to a high frequency power supply 37. The high frequency power supply 37 is configured to apply high frequency power, e.g., power having a frequency of 13.56 MHz, to the electrodes 33 and 34.

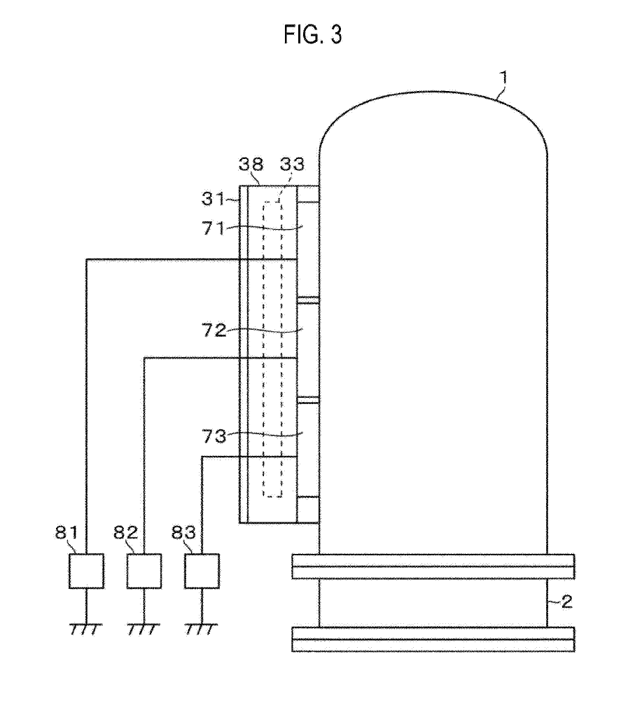

Insulation members 38 and 39 having concave cross-sections are disposed to extend vertically in order to surround the electrodes 33 and 34 outside the plasma-generating box 31 with spaces interposed between the insulation members 38 and 39 and the electrodes 33 and 34, respectively. Further, a plasma-adjusting conductor 7 is installed, for example, outside one insulation member 38, at a position close to the reaction tube 1 when viewed from the electrode 33. The plasma-adjusting conductor 7 has an L-shaped cross-section when viewed in a plan view, and is disposed to ride on respective sidewalls of the insulation member 38 and the plasma-generating box 31 at a junction therebetween. In this embodiment, the plasma-adjusting conductor 7 is divided into a plurality of conductors, e.g., three conductors as shown in FIG. 3, in the longitudinal direction of the reaction tube 1, wherein the three conductors are referred to as a first conductor 71, a second conductor 72 and a third conductor 73 from the top side. Each of the first to third conductors 71 to 73 is configured to have an elongated rectangular shape when viewed from its lateral side, for example, and the conductors are arranged one above another in the longitudinal direction of the reaction tube 1 to cover the plasma-generating box 31 from a bottom side to a top side thereof.

The first to third conductors 71 to 73 are grounded to a ground through impedance-adjusting circuits 81 to 83 as impedance-adjusting parts, respectively. In the following description, the plasma-adjusting conductor 7 may be used as a representative of the first to third conductors 71 to 73, and an impedance-adjusting circuit 8 may be used as a representative of the impedance-adjusting circuits 81 to 83. For example, as shown in FIG. 2, the impedance-adjusting circuit 8 includes a variable capacitor 841 and a variable inductor 842 connected in series to each other, a first switch 85 installed in series to the variable capacitor 841 and the variable inductor 842, and a second switch 86 installed in parallel to the first switch 85. The impedance-adjusting circuit 8 is configured to adjust impedance by changing the capacitance of the variable capacitor 841 and the inductance of the variable inductor 842. With this, adjustment ranges of the impedance-adjusting circuits 81 to 83 are configured to range from an impedance value corresponding to a grounded state of the plasma-adjusting conductor 7 to an impedance value corresponding to a floating state of the plasma-adjusting conductor 7.

For example, the impedance-adjusting circuits 81 to 83 are set to be in the floating state by turning off the first switch 85 and the second switch 86. Further, they are set to be in the ground state by turning off the first switch 85 while by turning on the second switch 86. Moreover, the impedance between the first to third conductors 71 to 73 and the ground may be adjusted by turning on the first switch 85, turning off the second switch 86, and changing the capacitance of the variable capacitor 841 and the inductance of the variable inductor 842. With this, the impedance between the first to third conductors 71 to 73 and the ground may be adjusted from the floating state to the ground state by a combination of changes in the capacitance of the variable capacitor 841 and the inductance of the variable inductor 842 and on/off operations of the first and second switches 85 and 86. For example, the capacitance of the variable capacitor 841 and the inductance of the variable inductor 842 are manually or automatically adjusted, and on/off states of the first and second switches 85 and 86 are set by a controller 100 described below. However, the on/off states of the first and second switches 85 and 86 may be set manually. Further, FIG. 2 shows a case where the plasma-adjusting conductor 7 (71) is set to be in the ground state by the impedance-adjusting circuit 8 (81).

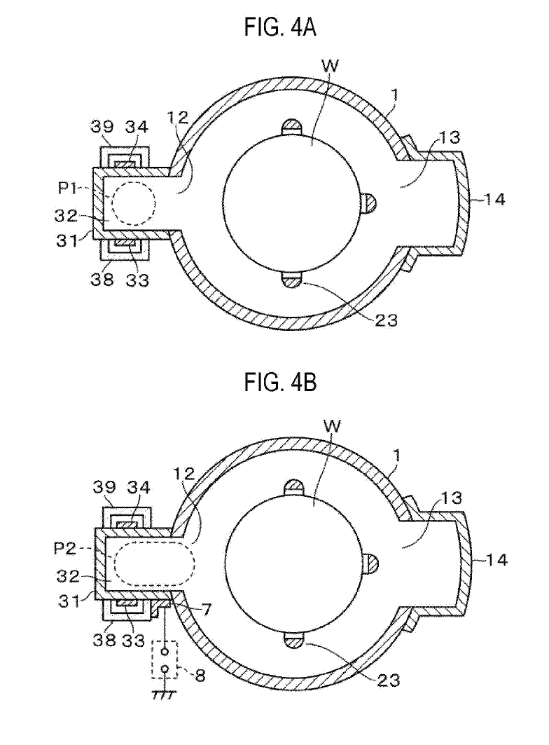

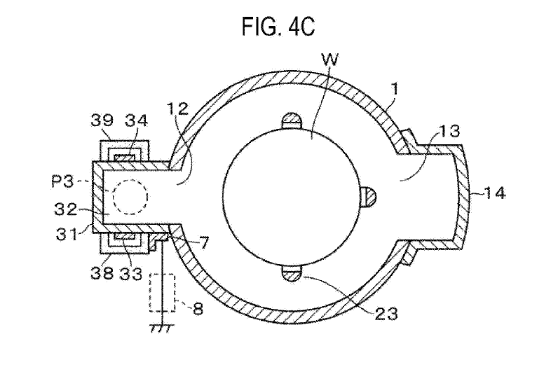

Functions of the plasma-adjusting conductor 7 and the impedance-adjusting circuit 8 will be described with reference to FIGS. 4A to 4C. FIG. 4A shows a configuration in which the plasma-adjusting conductor 7 is not installed, FIG. 4B shows a configuration in which the impedance-adjusting circuit 8 is set such that the plasma-adjusting conductor 7 is in the floating state, and FIG. 4C shows a configuration in which the impedance-adjusting circuit 8 is set such that the plasma-adjusting conductor 7 is in the ground state. Upon applying the high frequency power from the high frequency power supply 37, an electric field is generated from the electrodes 33 and 34 and capacitively-coupled plasma is generated and diffused in the plasma-generating chamber 32. Portions P1 to P3 indicated by dotted lines in FIGS. 4A to 4C schematically represent light-emitting areas of the plasma generated in the respective configurations. As the electric field is formed, by the electrodes 33 and 34, up to the areas where the wafers W are placed, although the plasma is not visually seen, it has been spread to the outside of the light-emitting areas.

As shown in FIG. 4B, when the plasma-adjusting conductor 7 is set to be in the floating state, the plasma-adjusting conductor 7 receives a potential of the electric field generated from the electrodes 33 and 34 and serves as an electrode. For this reason, as shown in this figure, the plasma light-emitting area P2 expands toward the reaction tube 1. Accordingly, when viewed from the wafers W in the reaction tube 1, the plasma is in a state where it is drawn toward the wafers W, so that the intensity of the plasma near the wafers W is increased.

Meanwhile, as shown in FIGS. 4A to 4C, when the plasma-adjusting conductor 7 is set to be in the ground state, the electric field generated from the electrodes 33 and 34 is absorbed into the plasma-adjusting conductor 7 and escapes through the plasma-adjusting conductor 7 into the ground, so that the intensity of the electric field is decreased. For this reason, the plasma light-emitting area P3 is reduced as compared with the case where the plasma-adjusting conductor 7 is not installed. Accordingly, the intensity of the plasma around the wafers W is decreased. It is noted that the impedance-adjusting circuit 8 is simplified in FIGS. 4B and 4C.

Further, the amplitude of the high frequency may be adjusted by changing the capacitance of the variable capacitor 841 and the inductance of the variable inductor 842 in the impedance-adjusting circuit 8, without destroying the matching of impedance seen from the high frequency power supply 37. In other words, by using the variable capacitor 841 and the variable inductor 842, a broad adjustment width for the amplitude of the high frequency can be secured and thus the plasma may be freely adjusted between a strong plasma state in the floating state of the plasma-adjusting conductor 7 and a weak plasma state in the ground state of the plasma-adjusting conductor 7. Roughly speaking, if the impedance becomes large (the plasma-adjusting conductor 7 approaches the floating state), the role of the plasma-adjusting conductor 7 as an electrode grows, and the plasma is biased toward the wafers W loaded on the wafer boat 23. On the contrary, if the impedance is decreased (the plasma-adjusting conductor 7 approaches the ground state), the degree of absorption of the electric field into the plasma-adjusting conductor 7 is increased, and the plasma may be weakened.

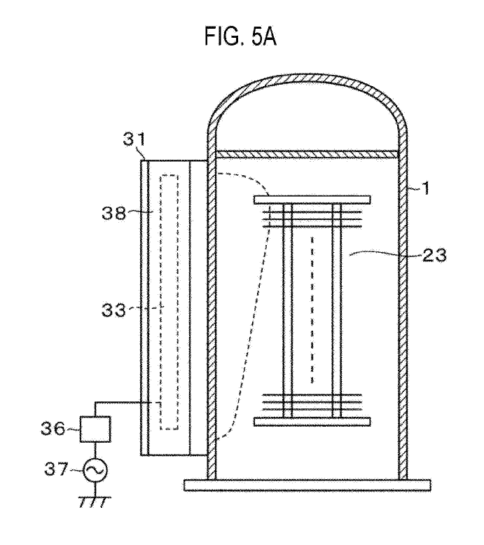

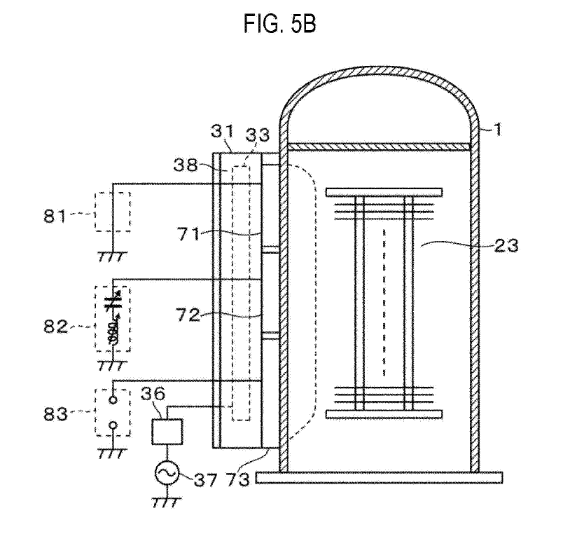

The apparatus in which the plasma is generated by the parallel plate electrodes as in this embodiment has a tendency in which the plasma is strong on the top side of the wafer boat 23 and weak on the bottom side of the wafer boat 23, as represented in FIG. 5A schematically showing the state of the plasma. Dotted lines in FIGS. 5A and 5B do not represent light-emitting areas of the plasma but are schematic lines obtained by vertically connecting points having an identical intensity of the plasma. FIG. 5A shows a configuration in which the plasma-adjusting conductor 7 is not installed. For this reason, in this example, the impedance-adjusting circuits 81 and 83 are set respectively such that the first conductor 71 on the top side is grounded to weaken the plasma while the third conductor 73 on the bottom side is in the floating state to strengthen the plasma, as shown in FIG. 5B. Further, the impedance-adjusting circuit 82 is set such that the impedance of the second conductor 72 on a central side has an impedance value between the impedance values of the ground and floating states. With this, the intensity of the plasma is kept constant in the arrangement direction of the wafers W. Since the impedance-adjusting circuits 81 to 83 can be separately connected to the respective first to third conductors 71 to 73 as described above to independently adjust the impedance, the intensity of plasma in the longitudinal direction of the reaction tube 1 (in the arrangement direction of the wafers W) can be adjusted.

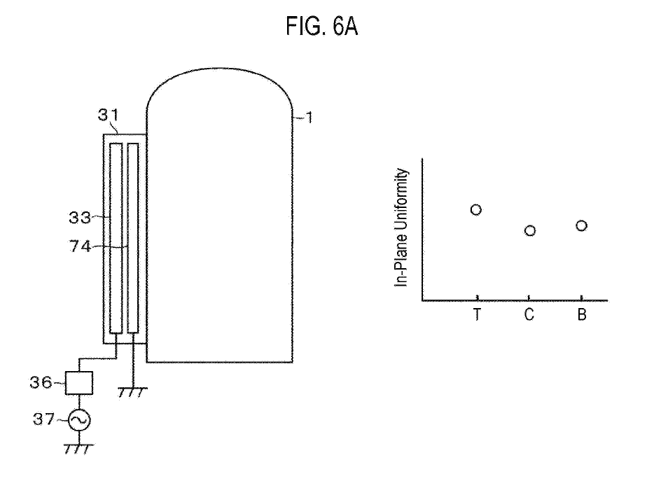

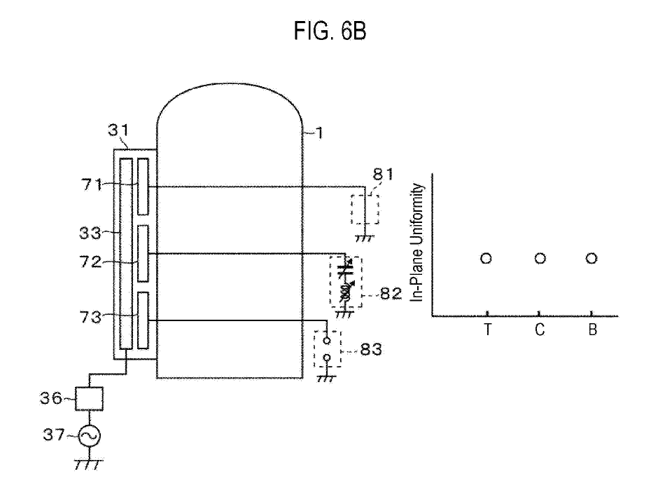

Meanwhile, FIG. 6A shows a configuration in which a plasma-adjusting conductor 74 that is not divided in the longitudinal direction of the reaction tube 1 is installed and grounded. Since the conductor 74 is grounded in this configuration, the plasma is weakened as compared with a configuration in which the conductor 74 is not installed, and the in-plane uniformity on the top side of the wafer boat 23 is improved. However, since a tendency of the intensity of the plasma to vary in the arrangement direction of the wafers W cannot be adjusted, the state of the plasma generated on the bottom side of the wafer boat 23 is so weak that the in-plane uniformity in the wafers W on the top and bottom sides of the wafer boat 23 is lowered. Meanwhile, right graphs in FIGS. 6A and 6B schematically show a relationship between the position of a wafer W in the wafer boat 23 and the in-plane uniformity of the film thickness of a thin film formed on the wafer W.

On the contrary, in the configuration of FIG. 6B showing this embodiment, the impedance of the first to third conductors 71 to 73 is adjusted such that the intensity of the plasma in the arrangement direction (in an inter-plane direction) of the wafers W is aligned with one another. For this reason, since the in-plane processing uniformity can be constant among the top side (T), the central side (C) and the bottom side (B) of the wafer boat 23, it is possible to secure good inter-plane uniformity (good uniformity in the arrangement direction of the wafers W).

The vertical heat treatment apparatus having the configuration described above is connected to the controller 100. The controller 100 consists of a computer having a CPU and a storage part, for example, and the storage part has a program recorded therein, which corresponds to a group of steps (instructions) organized for operations of the vertical heat treatment apparatus, e.g., for control when deposition processing is performed on wafers W in the reaction tube 1 in this example. This program is stored in a storage medium such as a hard disk, a compact disk, a magnetic optical disk and a memory card, and then installed from the storage medium to the computer.

An embodiment of a deposition method performed in the vertical heat treatment apparatus according to the present disclosure will be further described. First of all, a plurality of wafers W is loaded forming a shape of a shelf on the wafer boat 23; the wafer boat 23 is carried into the reaction tube 1 from the bottom side thereof; and the substrate carrying-in/out port is closed by the cover 21 to seal the reaction tube 1. Then, the inside of the reaction tube 1 is evacuated to have a vacuum atmosphere of a predetermined pressure by the evacuation mechanism 16 and heated to a predetermined temperature. Further, the wafer boat 23 is rotated by the rotation mechanism 24.

Then, in a state where the high frequency power supply 37 is turned off, a DCS gas is supplied into the reaction tube 1 by the gas nozzles 42 and 43. Since the reaction tube 1 is vacuum-evacuated via the evacuation port 13 provided opposing to the gas nozzles 42 and 43 with the wafer boat 23 interposed therebetween, the DCS gas flows though the reaction tube 1 from one side in the left and right direction of the reaction tube 1 toward the other side, so that molecules of the DCS gas are adsorbed onto a surface of each of the wafers W. Then, the supply of the DCS gas is interrupted and the N₂ gas is supplied into the reaction tube 1 to purge the remaining DCS gas. Subsequently, when the supply of the N₂ gas is interrupted, a discharge of the NH₃ gas from the gas nozzle 52 is initiated and the high frequency power supply 37 is turned on together with the discharge initiation of the NH₃ gas.

At this time, the impedance-adjusting circuit 81 of the first conductor 71 is set to be in the ground state, the impedance-adjusting circuit 82 of the second conductor 72 is set to have predetermined impedance, and the impedance-adjusting circuit 83 of the third conductor 73 is set to be in the floating state. The NH₃ gas discharged from the gas nozzle 52 is ionized in the plasma-generating chamber 32 to generate various active species such as N radicals, H radicals, NH radicals, NH₂ radicals and NH₃ radicals. These active species reach the entire surfaces of the wafers W, so that the DCS gas on the surfaces of the wafers W is nitrided by these radicals to form SiN film.

The first conductor 71 on the top side of the wafer boat 23 is set to be in the ground state so as to weaken the intensity of the plasma, while the third conductor 73 on the bottom side of the wafer boat 23 is set to be in the floating state to strengthen the intensity of the plasma. Further, the capacitance of the variable capacitor 841 and the inductance of the variable inductor 842 are adjusted in the impedance-adjusting circuit 82 of the second conductor 72 such that the intensity of the plasma on the central side of the wafer boat 23 is fitted between those on the top and bottom sides of the wafer boat 23. With this, since the intensity of the plasma is adjusted in the arrangement direction of the wafers W, it is possible to secure good processing uniformity in the arrangement direction.

Then, the supply of the NH₃ gas is interrupted and the N₂ gas is supplied to purge the remaining NH₃ gas and its decomposition products in the reaction tube 1. A cycle consisting of the supply of the DCS gas, the supply of active species of the NH3 gas and the purging as described above is repeated plural times, whereby thin SiN films are deposited one by one and a final SiN film of a desired film thickness is formed on the surface of each of the wafers W. After the processing is terminated, the wafer boat 23 is carried out from the reaction tube 1.

Further, the processing is not limited to the so-called ALD method described above but may be a CVD method in which the DCS gas and the NH₃ gas are simultaneously discharged.

According to the aforementioned embodiments, when viewed from the plasma-generating electrodes 33 and 34, the plasma-adjusting conductor 7 is installed at a position near the reaction tube 1 and the impedance-adjusting circuit 8 is also positioned between the plasma-adjusting conductor 7 and the ground. For this reason, since the degree of absorption of the electric field generated from the plasma-generating electrodes 33 and 34 into the conductor 7 is changed by adjusting the impedance between the conductor 7 and the ground, it is possible to adjust the intensity of the plasma. With this, the uniformity in the intensity of the plasma in the arrangement direction of the wafers W can be improved, so that the in-plane uniformity of the processing is constant in the arrangement direction. In the deposition processing previously described, the film thickness near the outer peripheral portion of the wafer W on the top side of the wafer boat 23 is prevented from being smaller than that in the central portion of the wafer W, so that the in-plane uniformity of the film thickness is constant in the arrangement direction. As a result, it is possible to improve the in-plane uniformity of the film thickness as well as the uniformity of the film thickness along the arrangement direction.

Further, the plasma-adjusting conductor 7 is divided into a plurality of conductors in the longitudinal direction of the reaction tube 1 and the impedance-adjusting circuit 8 is separately connected to the respective conductors 7, whereby the impedance between the respective conductors 7 and the ground may be independently adjusted. For this reason, the state of the plasma generated is more uniformly kept in the longitudinal direction of the reaction tube 1, so that the wafers W may be processed with better in-plane uniformity in the wafers W and with better uniformity in the arrangement direction of the wafers W. With this, processing reproducibility is improved, thereby enhancing productivity of the apparatus. Further, since the plasma-adjusting conductor 7 is installed outside the plasma-generating chamber 32 and the impedance-adjusting circuit 8 is installed between the plasma-adjusting conductor 7 and the ground, an existing apparatus can be also used and there is an advantage in that a considerable modification is not required in the apparatus.

### Second Embodiment

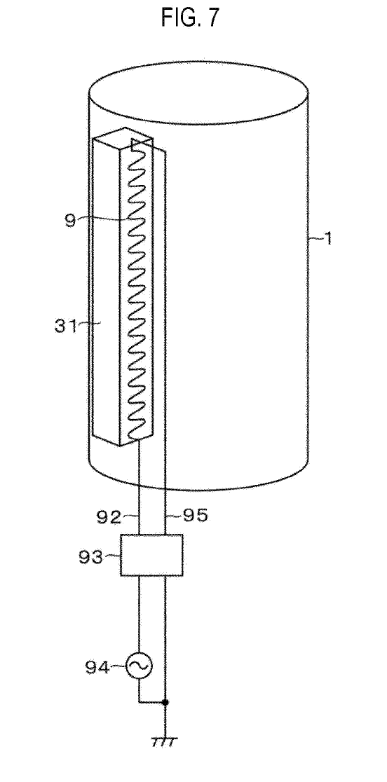

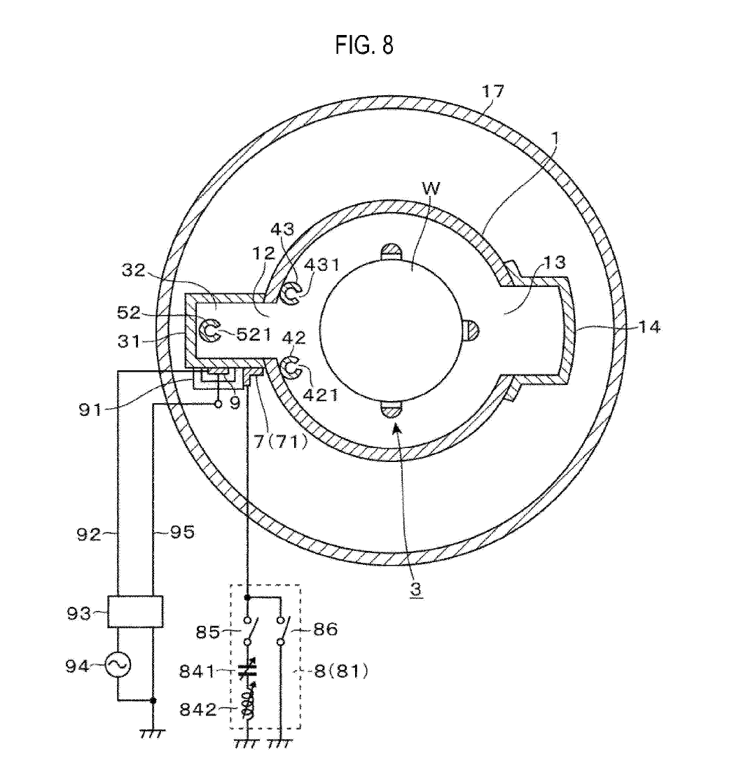

A second embodiment of a vertical heat treatment apparatus employing the substrate processing apparatus according to the present disclosure will be subsequently described with reference to FIGS. 7 to 9. A difference between this embodiment and the first embodiment is the configuration of the plasma-generating conductor. In this example, an electrode 9 making up a conductor for generating inductively-coupled plasma in the plasma-generating chamber 32 is installed to extend vertically from the bottom side to the top side of the plasma-generating box 31. The electrode 9 is configured to be repeatedly meandered back and forth while extending in the vertical direction, and hereinafter, referred to as a serpentine electrode 9. The serpentine electrode 9 is surrounded by an insulation member 91. For example, the serpentine electrode 9 is installed such that a leading end of the serpentine electrode 9 is bent in a direction opposite to the plasma-generating box 31 on the top side of the plasma-generating box 31 and then extends vertically downwards.

One end of a conductive line 92 is connected to a base end of the serpentine electrode 9, whereas the other end of the conductive line 92 is withdrawn outside the shield 17 and connected through a matching circuit 93 to a high frequency power supply 94. Further, the leading end of the serpentine electrode 9 is connected to one end of a conductive line 95. The other end of the conductive line 95 is withdrawn outside the shield 17 and bifurcated through the matching circuit 93, wherein one bifurcated end is grounded and the other bifurcated end is connected to the high frequency power supply 94. The high frequency power supply 94 is configured to apply high frequency power, e.g., power having a frequency of 13.56 MHz, to the serpentine electrode 9. Other configurations such as the reaction tube 1 or the shield 17, the first to third conductors 71 to 73 and the impedance-adjusting circuits 81 to 83 in this embodiment are identical to those in the first embodiment. The identical components are designated by the identical references numerals, and the description thereof will be omitted.

If high frequency power is applied from the high frequency power supply 94, an electric field is formed to be broad around the serpentine electrode 9, and the NH₃ gas discharged from the gas nozzle 52 toward the front side of the plasma-generating chamber 32 generates inductively-coupled plasma in the plasma-generating chamber 32. Then, various radicals such as NH₃ radicals are generated and supplied to the wafers W. The plasma-generating conductor is not limited to the serpentine electrode 9 and a coil-shaped electrode may be disposed, for example.

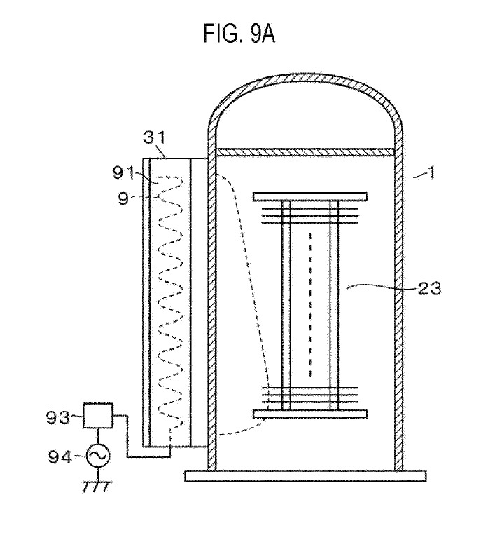

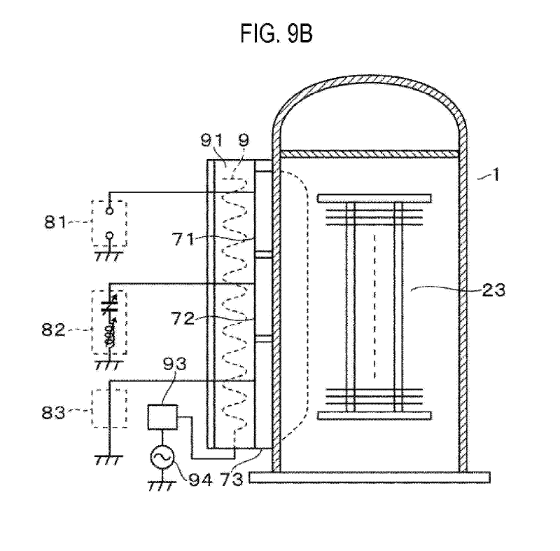

The apparatus in which the plasma is generated by the serpentine electrode 9 according to this embodiment has a tendency that the plasma is strong on the top side of the wafer boat 23 and weak on the bottom side of the wafer boat 23, as represented in FIG. 9A schematically showing the state of the plasma. FIG. 9A represents a configuration in which the plasma-adjusting conductor 7 is not installed, and dotted lines in FIGS. 9A and 9B do not represent light-emitting areas of the plasma but are schematic lines obtained by vertically connecting points having an identical intensity of the plasma. For this reason, in this example, the impedance-adjusting circuits 81 and 83 are set respectively such that the first conductor 71 on the top side is in the floating state to strengthen the plasma and the third conductor 73 on the bottom side is grounded to weaken the plasma in the floating state, as shown in FIG. 9B. Further, the impedance-adjusting circuit 82 is set such that the impedance of the second conductor 72 on the central side has an impedance value between the impedance values of the ground and floating states. With this, the intensity of the plasma is kept constant in the arrangement direction of the wafers W. Accordingly, even in this configuration, the in-plane uniformity of the processing along the arrangement direction of the wafers W can be kept constant, so that good in-plane uniformity and good uniformity in the arrangement direction may be secured.

The first to third conductors 71 to 73 are set such that the impedance between the respective conductors and the ground is different from one another in the first and second embodiments. However, it is sufficient to set the impedance between the ground and only at least two of the plurality of plasma-adjusting conductors 7 to be different from each other in the present disclosure. For example, in the first embodiment, the first conductor 71 may be set to be in the ground state, whereas the second and third conductors 72 and 73 may be set to be in the floating state or such that the impedance between the ground and the respective second and third conductors is identical to each other.

### Third Embodiment

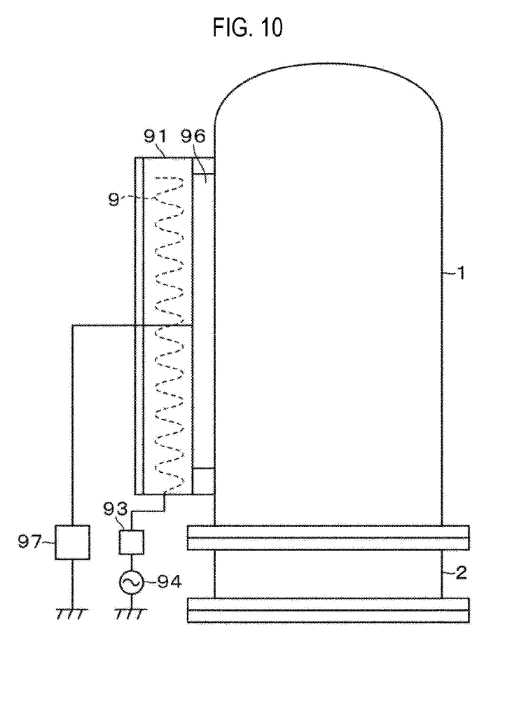

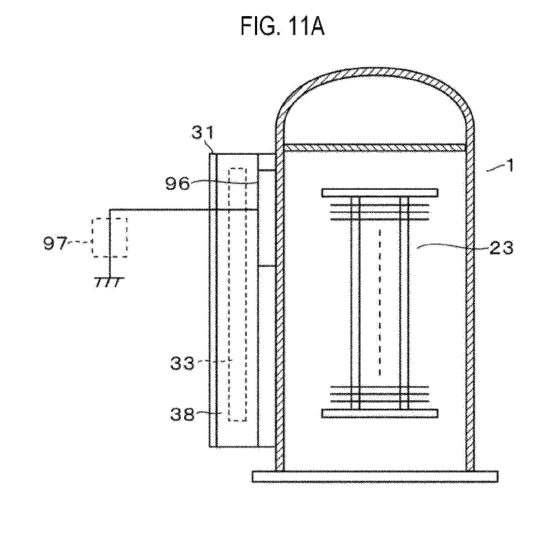

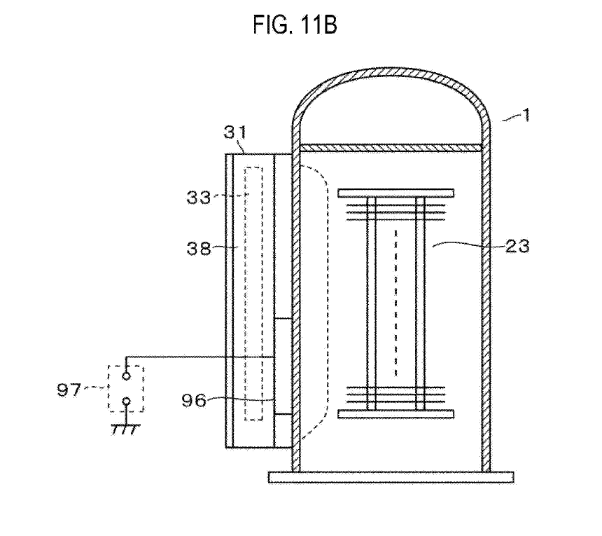

A third embodiment of a vertical heat treatment apparatus employing the substrate processing apparatus according to the present disclosure will be described with reference to FIGS. 10 and 11. A difference between this embodiment and the first and second embodiments is the configuration of the plasma-adjusting conductor. In this example, a plasma-adjusting conductor 96 is not divided but installed to extend vertically over almost all the length of the reaction tube 1. An impedance-adjusting circuit 97 configured in the same manner as the first and second embodiments is installed between the conductor 96 and the ground. Other configurations such as the reaction tube 1 or the shield 17 and the plasma-generating conductor in this embodiment are identical to those in the first or second embodiment. The identical components are designated by the identical reference numerals, and the description thereof will be omitted.

FIG. 10 shows a vertical heat treatment apparatus in which the conductor 96 according to this embodiment is installed in addition to the configuration having the plasma-generating serpentine electrode 9 according to the second embodiment. Since the plasma state can be controlled by adjusting the impedance between the conductor 96 and the ground through impedance-adjusting circuit 97, it is possible to adjust the intensity of the plasma in the arrangement direction of the wafers W. For this reason, it is possible to improve the in-plane uniformity of the processing as well as the uniformity in the arrangement direction.

Further, as shown in FIGS. 11A and 11B, the conductor 96 may be installed vertically over a portion of the length of the reaction tube 1. FIGS. 11A and 11B show an example in which the conductor 96 is installed to the configuration having the plasma-generating electrodes 33 and 34 according to the first embodiment. Since the plasma tends to be strong on the top side of the reaction tube 1 as previously described, the conductor 96 is installed at a position of a height corresponding to the top side of the reaction tube 1 in this vertical heat treatment apparatus, as shown in FIG. 11A, so that the conductor 96 may be set to be in a ground state or to have impedance close to that in the ground state by the impedance-adjusting circuit 97. With this, since the plasma can be weakened on the top side, the intensity of the plasma in the arrangement direction of the wafers W is kept constant. Alternatively, the conductor 96 may be installed at a position of a height corresponding to the bottom side of the reaction tube 1 as shown in FIG. 11B, so that the conductor 96 may be set to be in a floating state or to have impedance close to that in the floating state by the impedance-adjusting circuit 97. With this, since the plasma can be strengthened on the bottom side, the intensity of the plasma in the arrangement direction of the wafers W is kept constant. As a result, it is possible to improve the in-plane uniformity of the processing as well as the uniformity in the arrangement direction.

Although the plasma-adjusting conductor is installed near the reaction container when viewed from the plasma-generating conductor as described above, this position of the plasma-adjusting conductor is not limited to a region between the reaction container and the plasma-generating conductor. Even a position radially deviated from this region may be employed, so far as the intensity of the plasma at areas where the wafers are positioned can be adjusted. Further, the shape of the plasma-adjusting conductor is not limited to the configurations described above, and any shape capable of adjusting the intensity of the plasma, such as a rectangle when viewed in a plan view, may be utilized. Further, although the configurations of the first to third embodiments have been described in connection with the case where a single plasma-adjusting conductor is installed around the reaction container, two or more plasma-adjusting conductors may be disposed at different positions in a circumferential direction of the reaction container, for example, as in a case where two plasma-adjusting conductors are installed on opposite sidewalls of the plasma-generating chamber, respectively.

Further, the impedance-adjusting circuit making up the impedance-adjusting part is not limited to the aforementioned example, and it may be configured by using either of the variable capacitor and the variable inductor. Further, the impedance-adjusting circuit is not limited to the aforementioned configuration, so far as the impedance-adjusting circuit has a configuration in which the plasma-adjusting conductor and the ground can be separated when the floating state is set and in which the plasma-adjusting conductor, and the variable capacitor and the variable inductor (or either of the variable capacitor and the variable inductor) can be separately grounded when the ground state is set.

Further, when the plasma-adjusting conductor is divided and installed in the longitudinal direction of the reaction container, the impedance may be fixed to a predetermined impedance value, as in a case where the impedance of the divided conductors may be sequentially lowered from the top side toward the bottom side. That is, the plasma-adjusting conductor is not limited to a configuration with variable impedance. Further, when the plasma-adjusting conductor is divided and installed in the longitudinal direction of the reaction container, the plasma-adjusting conductor may include two plasma-adjusting conductors. For example, the reaction tube 1 may be divided into two areas so that the two plasma-adjusting conductors may be disposed to correspond to the two divided areas, respectively. Alternatively, the reaction tube 1 may be divided into three or more areas in the longitudinal direction thereof and the two plasma-adjusting conductors may be disposed in two of the three divided areas. For example, when the reaction tube 1 is divided into three areas in the longitudinal direction thereof, two plasma-adjusting conductors may be disposed only in areas on the top and bottom sides. When two plasma-adjusting conductors are installed, the impedance between the conductors and the ground may be different from each other or identical to each other. Further, when the plasma-adjusting conductor is divided and installed in the longitudinal direction of the reaction container, the divided conductors need not be necessarily arranged in the vertical direction. For example, the divided conductors on the top and central sides may be installed at different positions in the circumferential direction.

Although the case of depositing SiN film has been described by way of example above, the kind of film to be deposited is not specifically limited according to the present disclosure. Further, although plasma ALD processing has been described by way of example as the plasma processing, the present disclosure is not limited thereto but may be applied to all processing using plasma, such as plasma CVD processing, plasma modification processing, plasma oxidation and diffusion processing, plasma sputter processing and plasma nitriding processing.

### (Evaluation Tests)

Evaluation tests performed in connection with the present disclosure will be described. The vertical heat treatment apparatus shown in FIG. 10 previously described was used in the evaluation tests, wherein wafers were mounted in respective slots of the wafer boat 23 and ALD was performed in the sequence described in the embodiments to form SiN film. Deposition conditions were set such that processing pressure was 133 Pa (1 Torr) in DCS Adsorption and 39.9 Pa (0.3 Torr) in nitriding processing using plasma, processing temperature was 550 degrees C., a flow rate of the DCS gas was 1 L/min, and a flow rate of the NH₃ gas was 1 L/min. At this time, the deposition processing was performed respectively when the conductor 96 was set to be in the ground state (Example 1) and when the conductor 96 was set to be in the floating state (Example 2), and the in-plane uniformity of the film thickness was obtained for the wafers having films deposited according to Examples 1 and 2. The in-plane uniformity was calculated by measuring the film thicknesses of SiN film at 49 positions thereof including the center of each of the wafers and using the following formula (maximal film thickness−minimal film thickness)/(average film thicknesses×2). A lower value in the in-plane uniformity represents better uniformity.

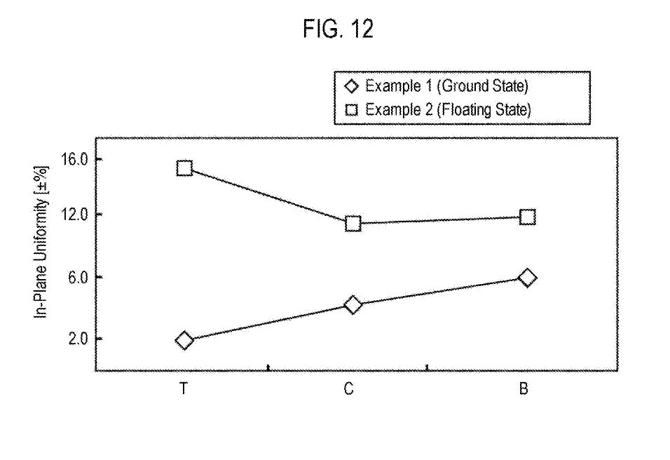

FIG. 12 shows results of the evaluation tests, wherein Example 1 (ground state) corresponds to a plot using symbol ⋄, while Example 2 (floating state) corresponds to a plot using symbol □. Further, the vertical axis represents the in-plane uniformity of the film thickness, while the top side T of the horizontal axis represents data of a 3^{rd} wafer from the top of the wafer boat, the central side C represents data of a 55^{th} wafer from the top of the wafer boat, and the bottom side B represents data of a 107^{th} wafer from the top of the wafer boat. It can be confirmed from FIG. 12 that the in-plane uniformity on the top side, the central side and the bottom side of the wafer boat 23 greatly varied depending on whether the conductor 96 was set to be in the ground state (Example 1) or in the floating state (Example 2). With this, it has been recognized that the in-plane uniformity of the film thickness can be adjusted by installing the plasma-adjusting conductor and adjusting the impedance between the plasma-adjusting conductor and the ground. It is also appreciated that data show a width of the in-plane uniformity when the conductor 96 was set to be in the ground state and when the conductor 96 was set to be in the floating state, and that the in-plane uniformity can be adjusted to a predetermined value by adjusting the capacitance of the variable capacitor and the inductance of the variable inductor in the impedance-adjusting circuit 97. Further, these evaluation tests are for confirming that the in-plane uniformity can be adjusted by adjusting the impedance of the conductor 96 rather than to improve the in-plane uniformity and are not for improving the in-plane uniformity.

In the present disclosure, the plasma-adjusting conductor is installed at a position near the reaction container when viewed from the plasma-generating conductor, and the impedance-adjusting part is positioned between the plasma-adjusting conductor and the ground. Since the degree of absorption of the electric field generated from the plasma-generating conductor into the plasma-adjusting conductor is changed by adjusting the impedance between the plasma-adjusting conductor and the ground, it is possible to adjust the intensity of the plasma. With this, the uniformity in the intensity of the plasma in the arrangement direction of the substrates is improved so that the in-plane uniformity of the processing is kept constant in the arrangement direction, whereby it is possible to improve the in-plane uniformity of the processing of the substrate as well as the uniformity in processing in the arrangement direction of the substrates.

Further, another embodiment of the present disclosure includes the plurality of plasma-adjusting conductors divided in the longitudinal direction of the reaction container, wherein the impedance between the ground and at least two of the plurality of divided plasma-adjusting conductors are set to be different from each other. For this reason, the intensity of the plasma in the arrangement direction of the substrates is more uniformly adjusted and the substrates may be processed with better in-plane uniformity in the substrates and with better uniformity in the arrangement direction of the substrates.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing apparatus in which a plurality of substrates is held in a shape of a shelf on a substrate holder, carried into a vertical reaction container and processed by a plasma-state process gas, comprising:
an evacuation mechanism configured to vacuum-evacuate an inside of the vertical reaction container;
a plasma-generating chamber configured to protrude toward an outside of the vertical reaction container and to extend in a vertical direction along a sidewall of the vertical reaction container;
a process gas-supplying part configured to supply a process gas to the substrates through the plasma-generating chamber;
a plasma-generating conductor installed vertically near the plasma-generating chamber outside the reaction container and connected to a high frequency power supply;
a plasma-adjusting conductor installed near the vertical reaction container, when viewed from the plasma-generating conductor outside the vertical reaction container; and
an impedance-adjusting part installed between the plasma-adjusting conductor and a ground.

2. The substrate processing apparatus of claim 1, wherein the plasma-adjusting conductor is divided into a plurality of conductors in a longitudinal direction of the vertical reaction container, and the impedance-adjusting part is installed between each of the divided conductors and the ground.

3. The substrate processing apparatus of claim 1, wherein an adjustment range of the impedance-adjusting part includes an impedance value corresponding to a ground state of the plasma-adjusting conductor.

4. The substrate processing apparatus of claim 1, wherein an adjustment range of the impedance-adjusting part includes an impedance value corresponding to a floating state of the plasma-adjusting conductor.

5. The substrate processing apparatus of claim 1, wherein the impedance-adjusting part includes a capacitor having a variable capacitance and an inductor having a variable inductance.

6. A substrate processing apparatus in which a plurality of substrates is held in a shape of a shelf on a substrate holder, carried into a vertical reaction container and processed by a plasma-state process gas, comprising:
an evacuation mechanism configured to vacuum-evacuate an inside of the vertical reaction container;
a plasma-generating chamber configured to protrude toward an outside of the vertical reaction container and to extend in a vertical direction along a sidewall of the vertical reaction container;
a process gas-supplying part configured to supply a process gas to the substrates through the plasma-generating chamber;
a plasma-generating conductor installed vertically near the plasma-generating chamber outside the vertical reaction container and connected to a high frequency power supply; and
a plasma-adjusting conductor installed near the vertical reaction container when viewed from the plasma-generating conductor outside the vertical reaction container and configured to be divided into a plurality of conductors in a longitudinal direction of the vertical reaction container,
wherein impedances between at least two of the divided conductors of the plasma-adjusting conductor and the ground are different from each other.
